(19) United States
(12) Patent Application Publication
(10) Pub. No.: US 2007/0296070 A1
(43) Pub. Date: Dec. 27, 2007

(54) Semiconductor package having functional and auxiliary leads, and process for fabricating it

(75) Inventor: Philippe Andre, Fontaine (FR)

Correspondence Address: GARDERE WYNNE SEWELL LLP;INTELLECTUAL PROPERTY SECTION, 3000 THANKSGIVING TOWER, 1601 ELM ST, DALLAS, TX, 75201-4761, US

(73) Assignee: STMicroelectronics S.A., Montrouge (FR)

(21) Appl. No.: 11/805,722

(22) Filed: May 23, 2007

(30) Foreign Application Priority Data
May 24, 2006 (FR) 06 04662

(51) Int. Cl. H01L 23/495; H01L 21/00

(52) U.S. Cl. 257/676; 438/127; 257/E23.031; 257/E23.124

(57) ABSTRACT

A semiconductor package and a process for fabricating such a package are presented. The package has a substantially parallelepipedal block, made of an encapsulation material. Embedded within the block is at least one integrated-circuit chip and a leadframe having functional leads for electrical connection to said chip. These functional leads emerge on the outside of said block via at least one side and are intended to be connected to a printed-circuit board. The leadframe does not have functional leads on at least one of the other sides of said block. For that other side, the leadframe includes auxiliary leads for electrical connection to said chip which emerge on the outside of said block via at least one of the sides of this block which do not have functional leads. These auxiliary lead are not intended to be connected to said printed-circuit board.

### PRIORITY CLAIM

The present application is a translation of and claims priority from French Application for Patent No. 06 04662 of the same title filed May 24, 2006, the disclosure of which is hereby incorporated by reference.

### BACKGROUND OF THE INVENTION

1. Technical Field of the Invention

The present invention relates to the field of semiconductor packages that comprise a substantially parallelepipedal block of an encapsulation material in which an integrated-circuit chip, a leadframe having electrical connection leads, and electrical connection wires connecting said leads to the contact pads of said chip are embedded, said electrical leads emerging on the outside of said block so as to be subsequently connected to a printed-circuit board.

2. Description of Related Art

At the present time, there are three ways of electrically testing and adjusting such components.

Either the test/adjustment operations are carried out directly on the integrated-circuit chip, before it is encapsulated. In this case, it is not possible to compensate for the variations that could result from the subsequent addition of the leadframe and from the encapsulation.

Or the test/adjustment operations are carried out on the finished package, the latter having leads specifically dedicated to these operations. The addition of such specifically dedicated leads means that larger leadframes have to be provided, requiring more encapsulation material and the soldering of these leads to the printed-circuit board, although these leads are subsequently useless. What are therefore obtained are larger packages that unnecessarily occupy space on the printed-circuit board.

Or the test/adjustment operations are carried out on the finished chip, the chip having an internal electronic test/adjustment structure such that certain leads can be used for carrying out these operations and can be used subsequently. This internal electronic structure requires the chip to be oversized, requires additional steps to fabricate it and more complex test/adjustment apparatus.

There is a need in the art to improve semiconductor packages so as to make it easier to carry out the test/adjustment operations on finished packages and possibly to increase the options of using such packages, in particular for performing subsequent programming operations on the chip.

### SUMMARY OF THE INVENTION

Embodiments herein relate more particularly to semiconductor packages comprising a substantially parallelepipedal block, made of an encapsulation material, in which at least one integrated-circuit chip and a leadframe are embedded, said leadframe having functional leads for electrical connection to said chip, which emerge on the outside of said block via at least one side and are intended to be connected to a printed-circuit board, said leadframe not having functional leads on at least one of the other sides of said block.

According to an embodiment, said leadframe also includes auxiliary leads for electrical connection to said chip, which emerge on the outside of said block via at least one of the sides of this block not having functional leads and are intended not to be connected to said printed-circuit board.

According to an embodiment, said auxiliary leads are preferably shorter than said functional leads.

According to one variant, said leadframe has functional leads on two opposed sides of said block and auxiliary leads on at least one of the other sides of this block not having functional leads.

According to another variant, said leadframe has functional leads on one of the sides of said block and auxiliary leads on at least one of the other sides of this block not having functional leads.

According to another variant, said leadframe has auxiliary leads on two opposed sides of said block.

Embodiments herein further concern a process for fabricating a semiconductor package comprising a substantially parallelepipedal block of encapsulation material, with at least one integrated-circuit chip being embedded in said material, a leadframe having electrical connection leads emerging on the outside of said block and electrical connection wires connecting said leads to contact pads on said chip, said electrical connection leads emerging on the outside of said encapsulation block.

According to an embodiment, this process comprises: fabricating a chip having functional electrical connection contact pads and auxiliary electrical connection contact pads; fabricating a leadframe having functional electrical connection leads on one side or on two opposed sides of the encapsulation block to be produced and auxiliary electrical connection leads on at least one side of the encapsulation block to be produced not having functional leads; selectively connecting, via electrical connection wires, on the one hand, the functional contact pads of the chip and the functional leads and, on the other hand, the auxiliary contact pads of the chip and the auxiliary leads; producing the encapsulation block; and cutting the functional leads and the auxiliary leads in such a way that the auxiliary leads are, on the outside of said block, shorter than the functional leads.

In another embodiment, a semiconductor package comprises: an integrated circuit chip having first pads associated solely with standard functions designed into the integrated circuit chip and further having second pads associated solely with testing of the integrated circuit chip; a leadframe to which the integrated circuit chip is attached, the leadframe including a first set of leads extending from a first side of the package, the first set of leads being electrically connected solely to the first pads, and further including a second set of leads extending from a second side of the package, the second set of leads being electrically connected solely to the second pads; and an encapsulating block embedding the leadframe and integrated circuit chip.

In still another embodiment, a process comprises: mounting an integrated circuit chip to a leadframe, the leadframe including a first set of leads extending in a first direction, the first set of leads being electrically connected solely to first pads of the integrated circuit chip associated solely with standard functions designed into the integrated circuit chip, and further including a second set of leads extending in a second direction perpendicular to the first direction, the second set of leads being electrically connected solely to second pads of the integrated circuit chip associated solely with testing of the integrated circuit chip; and embedding the leadframe and integrated circuit chip in an encapsulating block to form an integrated circuit device.

In yet another embodiment, a semiconductor package comprises: an integrated circuit chip having first pads associated solely with first functions designed into the integrated circuit chip for chip user and consumer use and further having second pads associated solely with second functions designed into the integrated circuit chip for use by others than the chip user and consumer; a leadframe to which the integrated circuit chip is attached, the leadframe including a first set of leads extending from a first side of the package, the first set of leads being electrically connected solely to the first pads, and further including a second set of leads extending from a second side of the package, the second set of leads being electrically connected solely to the second pads; and an encapsulating block embedding the leadframe and integrated circuit chip.

### BRIEF DESCRIPTION OF THE DRAWINGS

Other advantages and features will become apparent upon examining the detailed description of non-limiting embodiments and the appended drawings in which:

FIG. 1 shows a perspective view of a semiconductor package;

FIG. 2 shows a cross section of said package through its leadframe;

FIG. 3 shows a side view of said package on a test/adjustment apparatus;

FIG. 4 shows a side view of said package mounted on a printed-circuit board; and

FIG. 5 shows an integrated-circuit chip structure.

### DETAILED DESCRIPTION OF THE PREFERRED EMBODIMENTS

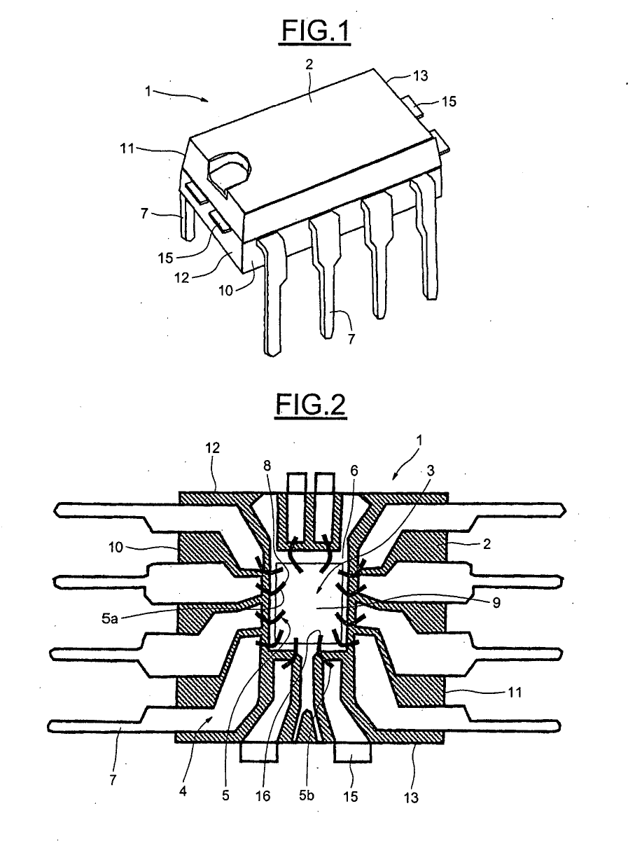

Referring in particular to FIGS. 1 and 2, it may be seen that a semiconductor package 1 comprises a substantially parallelepipedal block 2 of an encapsulation material, in which an integrated-circuit chip 3, a metal leadframe 4 and electrical connection wires 5 are embedded.

The leadframe 4 comprises a central platform 6 to which the chip 3 is bonded, a multiplicity of functional electrical connection leads 7, which extend to the periphery of the platform and emerge on the outside of the block 2, and electrical connection wires 5a selectively connecting these functional leads 7 to functional contact pads 8 on the chip 3 that are provided on a face 9 of the latter, opposite the platform 6.

In the example shown, the leadframe 4 has two sets of four functional leads 7 that emerge on the outside of the block 2 via two opposed sides 10 and 11 of this block 2.

Thus, no functional lead emerges from the block 2 via its two other opposed sides 12 and 13.

The leads needed for the standard use of the chip 3, so that the latter can fulfill its standard function(s) are called “functional leads 7”, some of which may also be intended for supplying power to the chip. For example, the chip 3 has integrated circuits giving it known microprocessor, memory, capacitor or other functions. The standard functions comprise those functions which are designed into the chip and for chip user or chip consumer use.

As shown in FIG. 4, these functional leads 7 are, outside the block 2, long enough to be soldered to a printed-circuit board 14.

The leadframe 4 also includes auxiliary leads 15 and electrical connection wires 5b that selectively connect these auxiliary leads 14 to an auxiliary contact pad 16 on the chip 3, these being provided on its face 9.

In the example shown, the leadframe 4 has two sets of two auxiliary leads 15 that emerge on the outside of the block 2 via those opposed sides 12 and 13 of this block 2 that do not have functional leads 7.

As shown in FIG. 4, the auxiliary leads 15 are, outside the block 2, much shorter than the functional leads 7 and are not connected to the printed-circuit board 14.

Leads that are not needed for the standard use of the chip 3 so that the latter can fulfill its standard function(s) are called “auxiliary leads 15”.

The auxiliary leads 15 are intended to allow the operations/functions of testing and adjusting the chip 3 to be carried out on the finished package 1 before it is mounted on a printed-circuit board. These testing and adjusting operations are also designed into the chip, but contrary to the standard functions are not for chip user or chip consumer use.

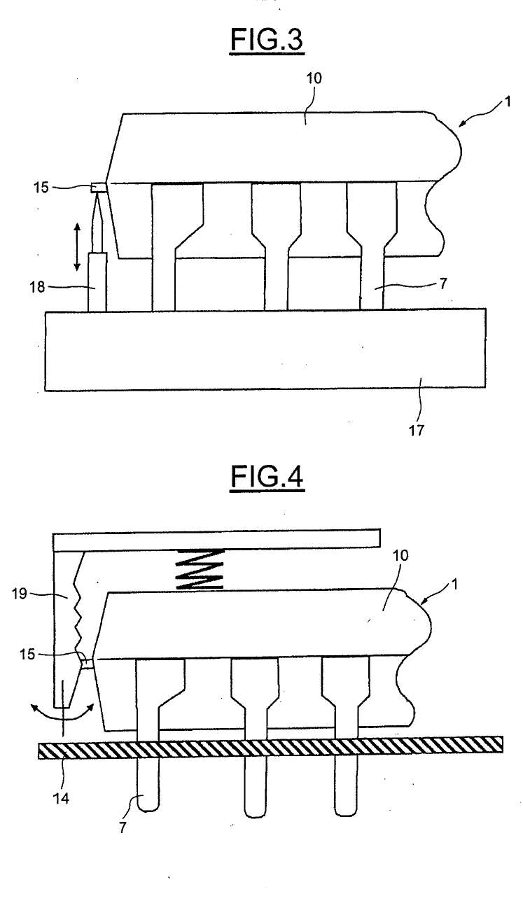

For example, as shown in FIG. 3, the package 1 is placed on the test/adjustment apparatus 17 in a position such that the functional leads 7 are connected to this apparatus. The apparatus 17 also includes projecting contact fingers 18 that come into contact with the auxiliary leads 15.

Moreover, the test/adjustment apparatus 17 may be designed to program the chip 3, for example via the auxiliary leads 15.

Furthermore, when the package 1 is mounted on the printed-circuit board, electrical intervention on the chip 3 is also possible via the auxiliary leads 15. All that is required to do this is to connect the auxiliary leads 15 to a programming apparatus, for example by means of contact arms 19.

It follows from the foregoing that the internal electronic structure of the chip 3 may be designed in a simplified manner that takes into account the existence of the functional leads 7 that are intended to be connected to a printed-circuit board and of the auxiliary leads 15 that will not be connected to such a board but which may be used for service operations for acting on the internal structure or the internal content of the chip 3. It is sufficient to provide functional contact pads 8 and identified auxiliary contact pads 16.

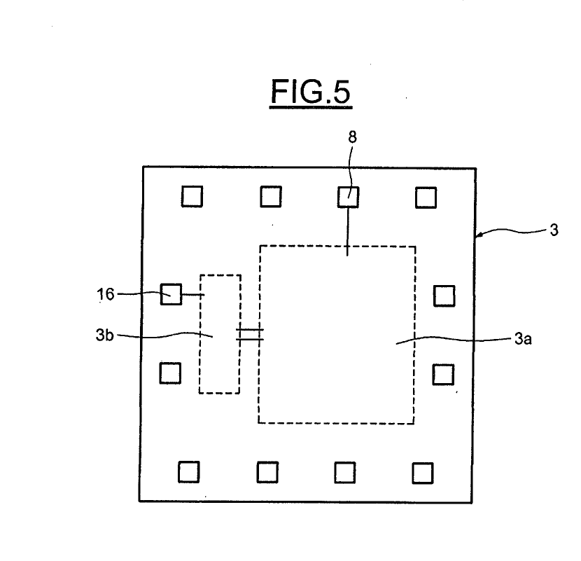

As a highly schematic example, FIG. 5 shows an integrated-circuit chip 3 that comprises a structure 3a consisting of functional electronic components, which structure is connected to the functional contact pads 8, and a structure 3b, consisting of auxiliary electronic components, structure 3b being connected to this structure 3a and connected to the auxiliary contact pads 16.

Moreover, the structure of the package does not modify the usual fabrication means. Specifically, it is necessary to provide, on a metal plate, adjacent locations on each of which the leadframe 4 is produced, to fasten a chip 3 to the platform 6 at each location, to place the electrical connection wires 5a and 5b, to produce an encapsulation block 2 on each location and then to cut the aforementioned metal plate in such a way that the functional leads 7 have a suitable length for mounting the package 1 on a printed-circuit board 14 and to cut the auxiliary leads 15 so that they have, outside the block 2, a length just sufficient for connecting them to an external apparatus.

The present invention is not limited to the example described above. It would be possible to provide functional leads 7 only on one side of the encapsulation block 2 and to provide auxiliary leads only on one side of the encapsulation block 2 having no functional leads. The number of functional leads 7 and the number of auxiliary leads 15 may also be different from those indicated. The connection means brought into contact with the auxiliary leads 15 could also be different. The shape of the auxiliary leads 15, outside the encapsulation block 2, could be adapted. They could be straight or bent at a certain distance from the sides of the encapsulation block 2, or pressed against the sides.

Many other embodiments are possible without departing from the scope of the appended claims.

Although preferred embodiments of the method and apparatus of the present invention have been illustrated in the accompanying Drawings and described in the foregoing Detailed Description, it will be understood that the invention is not limited to the embodiments disclosed, but is capable of numerous rearrangements, modifications and substitutions without departing from the spirit of the invention as set forth and defined by the following claims.

What is claimed is:

1. A semiconductor package comprising:
a substantially parallelepipedal block, made of an encapsulation material, in which at least one integrated-circuit chip and a leadframe are embedded,
wherein said leadframe has functional leads for electrical connection to said chip which emerge on the outside of said block via at least one side and are intended to be connected to a printed-circuit board, said leadframe not having functional leads on at least one of the other sides of said block,
wherein said leadframe includes auxiliary leads for electrical connection to said chip which emerge on the outside of said block via the at least one of the sides of this block not having functional leads and are intended not to be connected to said printed-circuit board.

2. The package according to claim 1, wherein said auxiliary leads are shorter in length than said functional leads.

3. The package according to claim 1, wherein said leadframe has functional leads on two opposed sides of said block and auxiliary leads on at least one of the other sides of this block not having functional leads.

4. The package according to claim 1, wherein said leadframe has functional leads on one of the sides of said block and auxiliary leads on at least one of the other sides of this block not having functional leads.

5. The package according to claim 1, wherein said leadframe has auxiliary leads on two opposed sides of said block.

6. A process for fabricating a semiconductor package comprising a substantially parallelepipedal block of encapsulation material, with at least one integrated-circuit chip being embedded in said material, a leadframe having electrical connection leads emerging on the outside of said block and electrical connection wires connecting said leads to contact pads on said chip, said electrical connection leads emerging on the outside of said encapsulation block, the process comprising:
fabricating a chip having functional electrical connection contact pads and auxiliary electrical connection contact pads;
fabricating a leadframe having functional electrical connection leads on one side or on two opposed sides of the encapsulation block to be produced and auxiliary electrical connection leads on at least one side of the encapsulation block to be produced not having functional leads;
selectively connecting, via electrical connection wires, on the one hand, the functional contact pads of the chip and the functional leads and, on the other hand, the auxiliary contact pads of the chip and the auxiliary leads;
producing the encapsulation block; and
cutting the functional leads and the auxiliary leads in such a way that the auxiliary leads are, on the outside of said block, shorter than the functional leads.

7. A semiconductor package, comprising:
an integrated circuit chip having first pads associated solely with standard functions designed into the integrated circuit chip and further having second pads associated solely with testing of the integrated circuit chip;
a leadframe to which the integrated circuit chip is attached, the leadframe including a first set of leads extending from a first side of the package, the first set of leads being electrically connected solely to the first pads, and further including a second set of leads extending from a second side of the package, the second set of leads being electrically connected solely to the second pads; and
an encapsulating block embedding the leadframe and integrated circuit chip.

8. The package of claim 7 wherein the second set of leads are shorter in length than the first set of leads.

9. The package of claim 7 wherein the second set of leads are configured so as to not allow for attachment to a printed circuit board receiving the package while the first set of leads are configured so as to allow for attachment to a printed circuit board receiving the package.

10. The package of claim 9 wherein the second set of leads extend only horizontally away from the package while the first set of leads extend generally vertically away from the package.

11. The package of claim 7 wherein the first and second sides of the package are adjacent sides.

12. The package of claim 7 wherein the second set of leads are not long enough to make contact with a printed circuit board to which the package is to be mounted while the first set of leads are long enough to make contact with a printed circuit board to which the package is to be mounted.

13. A process, comprising:
mounting an integrated circuit chip to a leadframe, the leadframe including a first set of leads extending in a first direction, the first set of leads being electrically connected solely to first pads of the integrated circuit chip associated solely with standard functions designed into the integrated circuit chip, and further including a second set of leads extending in a second direction perpendicular to the first direction, the second set of leads being electrically connected solely to second pads of the integrated circuit chip associated solely with testing of the integrated circuit chip; and
embedding the leadframe and integrated circuit chip in an encapsulating block to form an integrated circuit device.

14. The process of claim 13 further comprising configuring the second set of leads to be shorter in length than the first set of leads.

15. The process claim 13 further comprising configuring the second set of leads to extend only horizontally away from the encapsulating block while configuring the first set of leads to extend generally vertically away from the encapsulating block.

16. The process of claim 13 further comprising configuring the second set of leads to be too short to make contact with a printed circuit board to which the integrated circuit device is to be mounted while configuring the first set of leads to be long enough to make contact with a printed circuit board to which the integrated circuit device is to be mounted.

17. The process of claim 13 further comprising cutting the first leads and the second leads in such a way that the second leads are, on the outside of said encapsulating block, shorter than the first leads.

18. A semiconductor package, comprising:
an integrated circuit chip having first pads associated solely with first functions designed into the integrated circuit chip for chip user and consumer use and further having second pads associated solely with second functions designed into the integrated circuit chip for use by others than the chip user and consumer;
a leadframe to which the integrated circuit chip is attached, the leadframe including a first set of leads extending from a first side of the package, the first set of leads being electrically connected solely to the first pads, and further including a second set of leads extending from a second side of the package, the second set of leads being electrically connected solely to the second pads; and
an encapsulating block embedding the leadframe and integrated circuit chip.

19. The package of claim 18 wherein the second functions comprise testing and adjusting of the integrated circuit chip.

20. The package of claim 18 wherein the second set of leads are not long enough to make contact with a printed circuit board to which the package is to be mounted while the first set of leads are long enough to make contact with a printed circuit board to which the package is to be mounted.
